(19) United States
(12) Patent Application Publication
(10) Pub. No.: US 2023/0066135 A1
(43) Pub. Date: Mar. 2, 2023

(54) SEMICONDUCTOR DEVICE

(71) Applicant: SANKEN ELECTRIC CO., LTD., Niza-Shi (JP)

(72) Inventor: Toru YOSHIE, Hino-shi (JP)

(73) Assignee: SANKEN ELECTRIC CO., LTD., Niiza-Shi (JP)

(21) Appl. No.: 17/960,162

(22) Filed: Oct. 5, 2022

Related U.S. Application Data
(63) Continuation-in-part of application No. 17/411,389, filed on Aug. 25, 2021.

(51) Int. Cl. C30B 29/68; H01L 21/02; C30B 29/36; C30B 31/22; C30B 25/20

(52) U.S. Cl. CPC C30B 29/68; H01L 21/02378; H01L 21/02529; H01L 21/02694; C30B 29/36; C30B 31/22; C30B 25/20; C30B 19/04

(57) ABSTRACT

A semiconductor device and a method of manufacturing a semiconductor device according to one or more embodiments are disclosed. An interface layer is formed by implanting ionized impurities into a first layer comprising single-crystalline silicon carbide (SiC). Surfaces of the interface layer and a second layer comprising polycrystalline silicon carbide (SiC) are activated. The activated surfaces of the interface layer and the second layer are contacted and bonded. A covering layer is formed to cover a top surface and sides of the first layer, sides of the interface layer, and sides of the second layer.

### CROSS REFERENCE TO RELATED APPLICATIONS

This application is a continuation-in-part application of U.S. patent application Ser. No. 17/411,389, entitled “SEMICONDUCTOR DEVICE,” filed on Aug. 25, 2021, the entire contents of which are incorporated herein by reference.

### BACKGROUND

The present disclosure relates to a semiconductor device including silicon carbide (hereinafter simply referred to as SiC), and in particular, to a SiC semiconductor device that enables a formation of a semiconductor element in which a current flows perpendicularly to a substrate.

SiC is widely used as a material for semiconductor devices, not only because of its excellent corrosion resistance and heat resistance, but also because of its excellent electrical features. Japanese Patent Publication No. 2012-146694 (Patent Document 1) discloses a vertical semiconductor device substrate using SiC. The semiconductor device substrate includes a support substrate and single-crystalline SiC bonded to the support substrate. The support substrate includes a substrate including a material with lower specific resistance than that of single-crystalline SiC and a SiC thin film covering the substrate.

In a manufacturing process of the semiconductor device, single-crystalline SiC containing contaminants, such as chromium (Cr) may reduce yields in semiconductor manufacturing.

### SUMMARY

A semiconductor device according to one or more embodiments may include a first layer comprising single-crystalline silicon carbide (SiC); a second layer comprising polycrystalline silicon carbide (SiC), in contact with the first layer; and a covering layer that is arranged to cover sides of the first layer and the second layer, and a top surface of the first layer.

A method of manufacturing a semiconductor device according to one or more embodiments may include forming an interface layer by implanting ionized impurities into a first layer comprising single-crystalline silicon carbide (Sic); activating the interface layer and a second layer comprising polycrystalline silicon carbide (SiC); contacting and bonding the activated surfaces of the interface layer and the second layer; and forming a covering layer to cover a top surface and sides of the first layer, sides of the interface layer, and sides of the second layer.

### BRIEF DESCRIPTION OF DRAWINGS

FIG. 1 is a cross-sectional view illustrating a semiconductor device according to one or more embodiments;

FIG. 2 is a cross-sectional view illustrating a semiconductor device according to one or more embodiments;

FIG. 3 is a cross-sectional view illustrating a semiconductor device according to one or more embodiments;

FIG. 4 is a cross-sectional view illustrating a semiconductor device according to one or more embodiments;

FIG. 5 is a cross-sectional view illustrating a semiconductor device according to one or more embodiments;

FIG. 6 is a cross-sectional view illustrating a semiconductor device according to one or more embodiments;

FIG. 7 is a flowchart illustrating a manufacturing method of a semiconductor device according to one or more embodiments;

FIGS. 8A, 8B, 8C, and 8D are explanatory diagrams illustrating a manufacturing process of a semiconductor manufacturing method according to one or more embodiments; and

FIGS. 9A and 9B are explanatory diagrams illustrating a manufacturing process of a semiconductor manufacturing method according to one or more embodiments.

### DETAILED DESCRIPTION

A semiconductor device and its manufacturing method according to one or more embodiments are described. In the following descriptions when explaining the positional relationship of components, “top”, “bottom”, “side”, etc. are used as necessary based on an orientation of the referenced drawing, but these indications do not limit the technical concept of the invention.

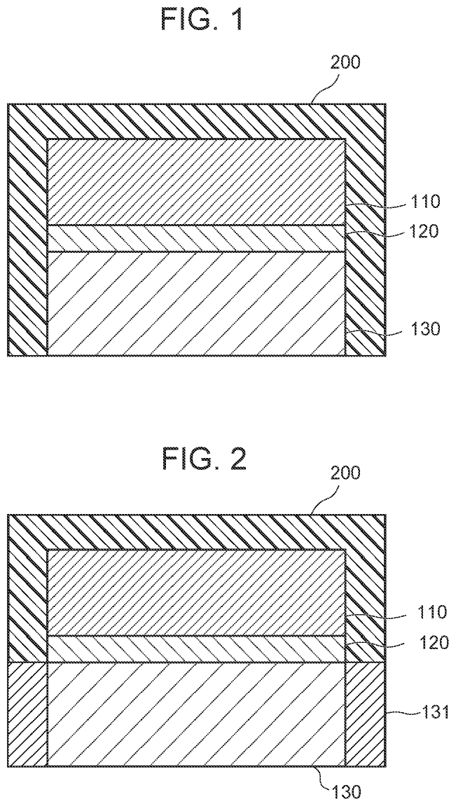

FIG. 1 is a cross-sectional view illustrating a semiconductor device according to one or more embodiments. The semiconductor device includes a first layer 110 mainly made of single-crystalline SiC, a second layer 130 mainly made of polycrystalline SiC. and an interface layer 120 that is provided at an interface between the first layer 110 and the second layer 130.

The first layer 110 may be mainly made of a compound semiconductor in which two or more elements are combined or may be mainly made of SiC. Single-crystalline SiC may be produced by a vapor phase method, a solution method, or an Acheson method. In the solution method, carbon (C) is melted into silicon (Si) melt containing chromium (Cr) or Si alloy solution containing chromium (Cr) in a crucible or other container. SiC is grown by depositing a SiC crystal layer on a seed crystal substrate installed in the container, which may lead to produce single-crystalline SiC. Single-crystalline SiC may include impurities other than single-crystalline SiC in the first layer 110. The impurities may be a first transition element, chromium (Cr), or a compound with chromium. An impurity concentration may be from 1×10¹⁶ atoms/cm³ to 1×10¹⁹ atoms/cm³ and in particular, may be from 1×10¹⁷ atoms/cm³ to 1×10¹⁸ atoms/cm³. The first layer 110 may be free of specified impurities other than single-crystalline SiC. The maximum thickness of the first layer 110 may be determined by the implantation of the ion implanter. Considering the peeling by stealth laser ablation, the maximum thickness of the first layer 110 may be several μm. The thickness of the first layer 110 may be from 0.1 μm to 5 μm, and preferably from 0.3 μm to 1 μm in terms of maintaining a crystal quality.

The interface layer 120 is provided to be sandwiched between the first layer 110 and the second layer 130, and is provided at an interface between the first layer 110 and the second layer 130. The interface layer 120 may be mainly made of a compound semiconductor in which two or more elements are combined, or may be mainly made of SiC. The interface layer 120 may be single-crystalline SiC with phosphorus (P). The interface layer 120 may be formed by ion implantation with impurities, such as phosphorus (P), arsenic (As), nitrogen (N), etc., on a surface of the first layer 110. The impurity concentration in the case, 1×10¹⁹ atoms/cm³ to 1×10²² atoms/cm³ may be preferable for phosphorus. 1×10²⁰ atoms/cm³ to 5×10²¹ atoms/cm³ may be more preferable because of an effect of reducing a contact resistance of the interface layer 120. The thinner value of the thickness of the interface layer may be determined based on the variation in the resistance value of the interface layer. In addition, the thicker value of the thickness of the interface layer may be determined based on the resistance value of the interface layer. The thickness of the interface layer 120 may be from 500 Å to 5000 Å, and preferably from 1000 Å to 3000 Å in terms of an effect of reducing the resistance value of the interface layer 120. The contact resistance between the first layer 110 and the second layer 130 may be reduced by including impurities in the interface layer 120. When the first layer 110 includes chromium and the interface layer 120 is formed by ion implantation with phosphorus (P) on the surface of the first layer 110, the concentration of phosphorus may preferably be higher than the concentration of chromium in the first layer 110. The interface layer 120 may be an alloy of chromium and phosphorus (CrP alloy). The composition ratio of chromium and phosphorus of the interface layer 120 may be 1:10000 when the impurity concentration of phosphorus is 1×10²⁰ atoms/cm³ and the impurity concentration of chromium is 1×10¹⁶ atoms/cm³.

The second layer 130 may be mainly made of a compound semiconductor in which two or more elements are combined or may be mainly made of SiC. The second layer 130 may be polycrystalline SiC having a structure that includes a plurality of crystallites, each of which may have a different crystalline axis direction. The polycrystalline SiC may be 3C—SiC, 4H—SiC, 6H—SiC, 8H—SiC, 10H—SiC, 15R—SiCl, or a mixture including multiple above-mentioned crystals. The second layer 130 may include specified impurities, or may not include any impurities at all. The second layer 130 may be polycrystalline SiC with nitrogen (N). The thickness of the second layer 130 may preferably be from 100 μm to 1000 μm, and more preferably from 300 μm to 800 μm in terms of improving the durability of the semiconductor device.

A covering layer 200 is provided to cover the first layer 110, the interface layer 120, and the second layer 130. As illustrated in FIG. 1, the covering layer 200 is provided to cover sides and a top surface of the first layer 110, sides of the interface layer 120, and sides of the second layer 130. The covering layer 200 may include single-crystalline SiC, and a single-crystalline SiC layer may be formed by epitaxial growth to cover the first layer 110, the interface layer 120, and the second layer 130. The thickness of the covering layer 200 may be from 5 μm to 15 μm. The covering layer 200 may be substantially made of materials that have atomic arrangement, suppress Cr (chromium) diffusion, and have heat-resistant. The covering layer 200 may be substantially made of Al₂O₃, SiN, or SiC.

Thus, the semiconductor device according to one or more embodiments includes a structure, in which at least the first layer 110 is covered by the covering layer 200. The structure may reduce contamination by contaminants included in the first layer 110 in a semiconductor manufacturing process, thereby improving yields in semiconductor manufacturing.

FIG. 2 is a cross-sectional view illustrating a semiconductor device according to one or more embodiments. As illustrated in FIG. 2, the covering layer 200 and a covering layer 131 are provided to cover the first layer 110, the interface layer 120, and the second layer 130. As illustrated in FIG. 2, the covering layer 200 is provided to cover the sides and top surface of the first layer 110 and the sides of the interface layer 120. The covering layer 131 is provided to cover the sides of the second layer 130. The covering layer 200 may include SiC, and a single-crystalline SiC layer may be formed by epitaxial growth to cover the sides of the first layer 110 and the interface layer 120 and the top surface of the first layer 110. The thickness of the covering layer 200 may be from 5 μm to 15 μm. A polycrystalline SiC layer may be formed by epitaxial growth to cover the sides of the second layer 130 as the covering layer 131. The thickness of the covering layer 131 may be from 5 μm to 15 μm. The covering layer 200 may include polycrystalline SiC and may be integrally formed with the second layer 130. The covering layer 200 may also be a part of the second layer 130.

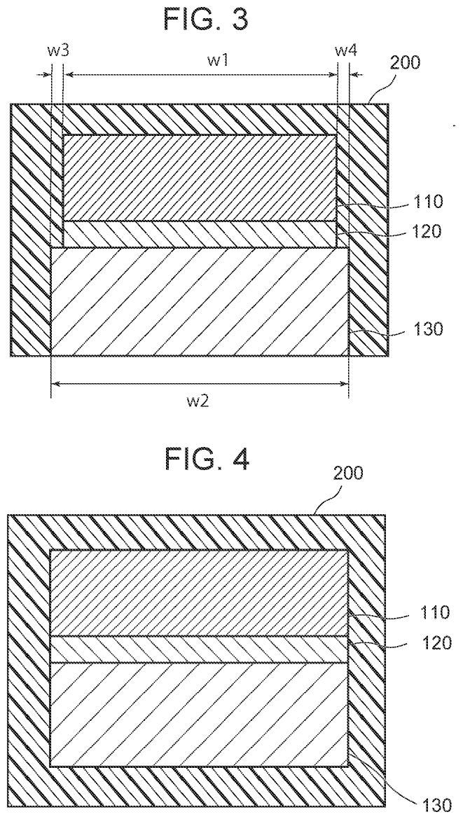

FIG. 3 is a cross-sectional view illustrating a semiconductor device according to one or more embodiments. As illustrated in FIG. 3, the covering layer 200 is provided to cover the first layer 110, the interface layer 120, and the second layer 130. As illustrated in FIG. 3, the covering layer 200 is provided to cover the sides and top surface of the first layer 110, the sides of the interface layer 120, and the sides of the second layer 130. The covering layer 200 may include SiC, and a single-crystalline SiC layer may be formed by epitaxial growth to cover the first layer 110, the interface layer 120, and the second layer 130. The thickness of the covering layer 200 may be from 5 μm to 15 μm. Widths of the first layer 110 and the interface layer 120 are a width w1, and the width of the second layer 130 is a width w2, which is different from the width w1. Specifically, the widths of the first layer 110 and the interface layer 120 are the width w1, and the width of the second layer 130 is the width w2, which is greater than the width w1. Therefore, even when the widths of the first layer 110, the interface layer 120, and the second layer 130 are different, the covering layer 200 may be provided to cover the first layer 110, the interface layer 120, and the second layer 130. Even in the above-mentioned case, contamination by impurities included in the first layer 110 may be reduced in a semiconductor manufacturing process, thereby improving yields in semiconductor manufacturing.

In FIG. 3, the widths of the first layer 110 and the interface layer 120 are a width w1, and the width of the second layer 130 is a width w2, which is greater than the width w1, but is not limited to. The widths of the first layer 110 and the interface layer 120 are the width w1, and the width of the second layer 130 may be the width w2, which is smaller than the width w1. In addition, the difference between the widths of the first layer 110 and the interface layer 120 and the width of the second layer 130 may be symmetrical. In that case, the difference between the widths of the first layer 110 and the interface layer 120 and the width of the second layer 130 may be from 1 mm to 3 mm on each side. Thus, in FIG. 3, widths w3 and w4 may be from 1 mm to 3 mm, but is not limited to. The second layer 130 may be provided shifting from the center of a width direction of the first layer 110 and the interface layer 120. In the semiconductor device illustrated in FIG. 3, the widths of the first layer 110 and the interface layer 120 are the width w1, and the width of the second layer 130 is the width w2, but is not limited to. For example, the width of the first layer 110 may be the width w1, and the widths of the second layer 130 and the interface layer 120 may be the width w2, which are greater than the width w1.

FIG. 4 is a cross-sectional view illustrating a semiconductor device according to one or more embodiments. As illustrated in FIG. 4, the covering layer 200 is provided to cover the first layer 110, the interface layer 120, and the second layer 130. As illustrated in FIG. 4, the covering layer 200 is provided to cover the sides and top surface of the first layer 110, the sides of the interface layer 120, the sides of the second layer 130, and a bottom surface of the second layer 130. The covering layer 200 may include SiC, and a single-crystalline SiC layer may be formed by epitaxial growth to cover the first layer 110, the interface layer 120, and the second layer 130. The thickness of the covering layer 200 may be from 5 μm to 15 μm. As illustrated in FIG. 4, the covering layer 200 is also provided on the bottom surface of the second layer 130. Even in the case, contamination by impurities included in the first layer 110 may be reduced during the semiconductor manufacturing process, thereby improving yields in semiconductor manufacturing.

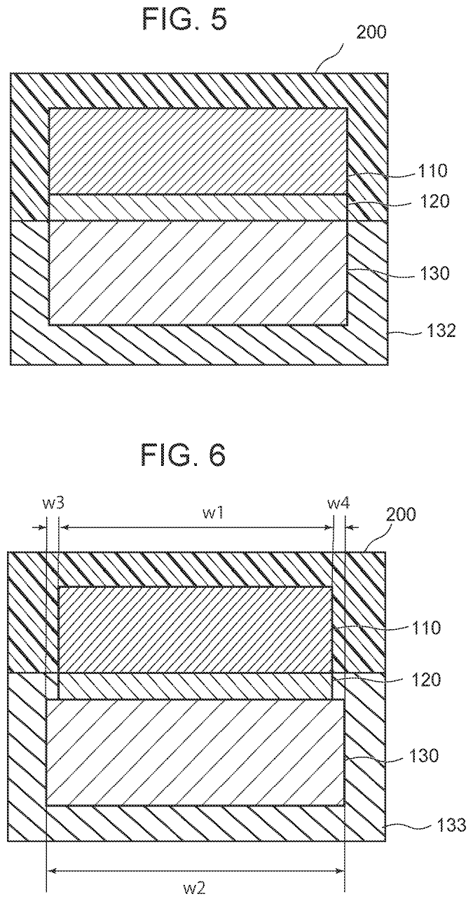

FIG. 5 is a cross-sectional view illustrating a semiconductor device according to one or more embodiments. As illustrated in FIG. 5, the covering layer 200 and a covering layer 132 are provided to cover the first layer 110, the interface layer 120, and the second layer 130. As illustrated in FIG. 5, the covering layer 200 is provided to cover the sides and top surface of the first layer 110 and the sides of the interface layer 120. The covering layer 132 is provided to cover the sides and bottom surface of the second layer 130. The covering layer 200 may include SiC, and a single-crystalline SiC layer may be formed by epitaxial growth to cover the first layer 110 and the interface layer 120. The thickness of the covering layer 200 may be from 5 μm to 15 μm. A polycrystalline SiC layer may be formed by epitaxial growth to cover the sides and bottom surface of the second layer 130 as the covering layer 132. The thickness of the covering layer 132 may be from 5 μm to 15 μm. The covering layer 132 may include polycrystalline SiC and may be formed integrally with the second layer 130. The covering layer 132 may also be a part of the second layer 130. In the semiconductor device illustrated in FIG. 5, contamination by impurities included in the first layer 110 may be reduced in the semiconductor manufacturing process, thereby improving yields in semiconductor manufacturing.

FIG. 6 is a cross-sectional view illustrating a semiconductor device according to one or more embodiments. As illustrated in FIG. 6, the covering layer 200 and a covering layer 133 are provided to cover the first layer 110, the interface layer 120, and the second layer 130. As illustrated in FIG. 6, the covering layer 200 is provided to cover the top surface and sides of the first layer 110. The covering layer 133 is provided to cover the sides of the interface layer 120 and the sides and bottom surface of the second layer 130. The covering layer 200 may include SiC, and a single-crystalline SiC layer may be formed by epitaxial growth to cover the first layer 110. The thickness of the covering layer 200 may be from 5 μm to 15 μm. A polycrystalline SiC layer may be formed by epitaxial growth to cover the sides of the interface layer 120 and the sides and bottom surface of the second layer 130 as the covering layer 133. The thickness of the covering layer 133 may be from 5 μm to 15 μm. The covering layer 133 may include polycrystalline SiC and may be formed integrally with the second layer 130. The covering layer 133 may also be a part of the second layer 130. The widths of the first layer 110 and the interface layer 120 are a width w1, and the width of the second layer 130 is a width w2, which is different from the width w1. Specifically, the widths of the first layer 110 and the interface layer 120 are the width w1, and the width of the second layer 130 is the width w2, which is greater than the width w1. Thus, even when the widths of the first layer 110, the interface layer 120, and the second layer 130 are different, the covering layer 200 may be provided to cover the first layer 110. Even in the case, contamination by impurities included in the first layer 110 may be reduced in the semiconductor manufacturing process, thereby improving yields in semiconductor manufacturing.

In FIG. 6, the widths of the first layer 110 and the interface layer 120 are a width w1, and the width of the second layer 130 is a width w2, which is greater than the width w1, but is not limited to. The widths of the first layer 110 and the interface layer 120 may be the width w1, and the width of the second layer 130 may be the width w2, which is smaller than the width w1. The difference between the widths of the first layer 110 and the interface layer 120 and the width of the second layer 130 may be symmetrical. In that case, the difference between the widths of the first layer 110 and the interface layer 120 and the width of the second layer 130 may be from 1 mm to 3 mm on each side. Thus, in FIG. 6, widths w3 and w4 may be from 1 mm to 3 mm, but is not limited to. The second layer 130 may be provided by shifting from the center of the width direction of the first layer 110 and the interface layer 120. In the semiconductor device illustrated in FIG. 6, the widths of the first layer 110 and the interface layer 120 are the width w1, and the width of the second layer 130 is the width w2, but is not limited to. For example, the width of the first layer 110 may be the width w1, and the widths of the second layer 130 and the interface layer 120 may be the width w2, which is greater than the width w1.

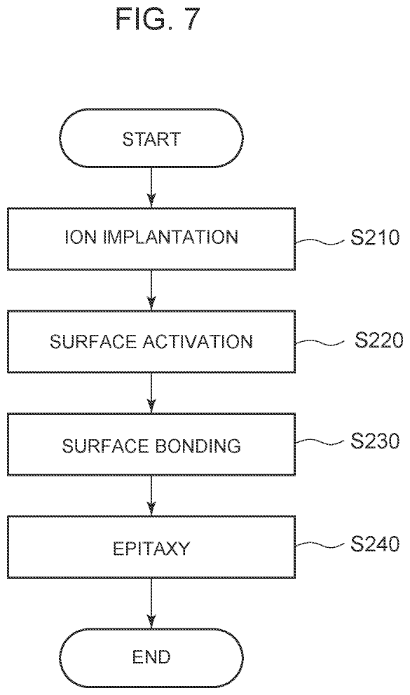

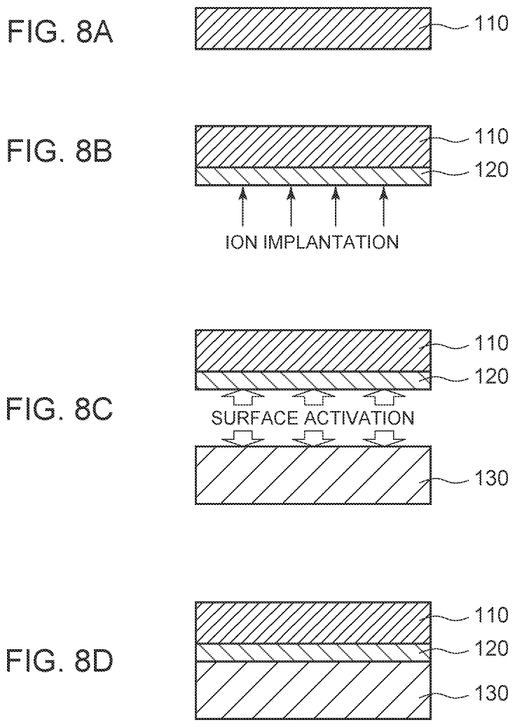

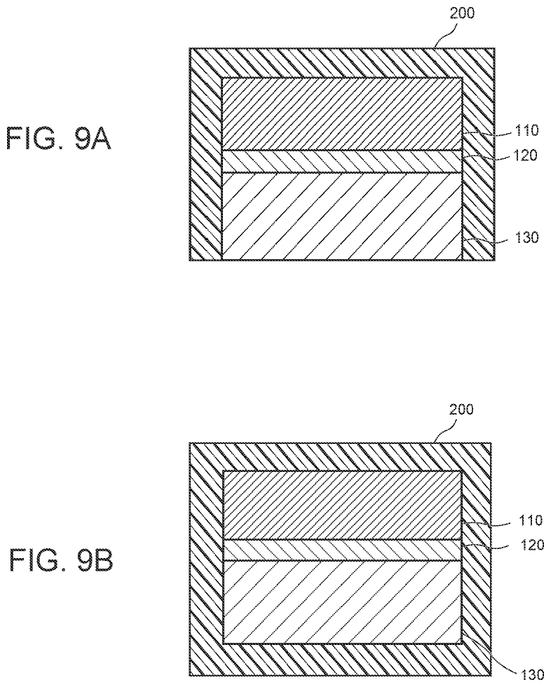

A method of manufacturing a semiconductor device according to one or more embodiments is described with reference to drawings. FIG. 7 is a flowchart illustrating a manufacturing method of a semiconductor device according to one or more embodiments. FIGS. 8A, 8B, 8C, and 8D, and FIGS. 9A and 9B are explanatory diagrams illustrating a manufacturing process of a semiconductor manufacturing method according to one or more embodiments.

Ionized impurities are implanted into the first layer 110 in step S210. The first layer 110 with pretreatment for ion implantation, such as surface planarization, etc., is prepared (FIG. 8A). The first layer 110 may include impurities, such as chromium (Cr). Ion implantation is performed on a surface of the first layer 110 (FIG. 8B). The impurities to be ion implanted may be phosphorus (P), arsenic (As), nitrogen (N), etc., and phosphorus may be more preferable. In an ion implantation process, an acceleration energy from 10 keV to 100 keV may be preferable, and 20 keV to 60 keV may be more preferable. As for a dosage of impurities, 1×10¹⁹/cm³ or more may be preferable, and 1×10²¹/cm³ or more may be more preferable in terms of the effect of reducing the resistance of the interface layer 120 to be formed. For example, the interface layer 120 with a thickness of 1000 A may be formed under conditions of an acceleration energy of 10 keV and a dose of 1×10²⁰/cm³

In step S220, a surface activation process of the interface layer 120 and the second layer 130 is performed. In an embodiment, the activation process is applied to the surface of the interface layer 120 formed on the first layer 110. For example, gas is ionized by high-frequency plasma in a high vacuum or ultrahigh vacuum, and the gas is irradiated to the surfaces of the interface layer 120 formed on the first layer 110 and the second layer 130. The irradiation removes oxide films, adhesions, etc. (FIG. 8C). A bonding hand (dangling bond) of surface atoms may be produced by the removal of the oxide films and adhesions. The gas may include inert gas, such as argon (Ar), neon (Ne), xenon (Xe), etc.

In step S230, the surface of the interface layer 120 and the surface of the second layer 130 are contacted and bonded (FIG. 8D). Bonding may be used to bond the surface of the interface layer 120 to the surface of the second layer 130. Thermocompression bonding may be performed at a temperature of 1500° C. in a vacuum environment. The surface of the semiconductor device produced in the method may be polished by Chemical Mechanical Polishing (CMP).

In step S240, the covering layer 200 is formed to cover the first layer 110, the interface layer 120, and the second layer 130. The covering layer 200 may be substantially made of SiC, and a single-crystalline SiC layer may be formed by epitaxial growth to cover the first layer 110, the interface layer 120, and the second layer 130. The thickness of the covering layer 200 may be from 5 μm to 15 μm. The covering layer 200 may be provided to cover the sides of the first layer 110, the interface layer 120, and the second layer 130 (FIG. 9A). The covering layer 200 may also be provided to cover the sides of the first layer 110, the interface layer 120, and the second layer 130 and the bottom surface of the second layer 130 (FIG. 9B).

The semiconductor device manufactured by the above-mentioned method forms the interface layer 120 including chromium and phosphorus, for example, at an interface between the first layer 110, which may be substantially made of a single-crystalline and the second layer 130, which is a polycrystalline substrate, and thus may reduce electrical resistance of the interface between the first layer 110 and the second layer 130. Therefore, a semiconductor device with a good current characteristic in a direction across the interface may be provided. In addition, covering a substrate including impurities in the semiconductor device with the covering layer may reduce contamination by impurities included in the semiconductor device during the semiconductor manufacturing process, which may improve yields in semiconductor manufacturing.

In general, single and polycrystalline SiC have a high density as a material due to the short Si—C interatomic distance in atomic density. Therefore, metal diffusion hardly occurs. The semiconductor according to one or more embodiments have a covering layer including SiC. The covering layer is used to confine Cr to avoid spreading into the environment and to avoid to incorporation into other semiconductors.

The scope of the invention however is not limited to the above-described embodiments, and various modifications can be made within the scope of the claims, and one or more embodiments obtained by appropriately combining the technical means disclosed in the different embodiments are also included in the technical scope of the invention.

1. A semiconductor device comprising:
a first layer comprising single-crystalline silicon carbide (SiC);
a second layer comprising polycrystalline silicon carbide (SiC), in contact with the first layer; and
a covering layer that is arranged to cover sides of the first layer and the second layer, and a top surface of the first layer.

2. The semiconductor device according to claim 1, wherein
the first layer comprises chromium (Cr).

3. The semiconductor device according to claim 1, wherein
the second layer comprises nitrogen (N).

4. The semiconductor device according to claim 1, wherein
the first layer comprises an interface layer that is arranged in contact with the second layer, the interface layer comprising chromium (Cr) and nitrogen (N).

5. The semiconductor device according to claim 1, wherein
the first layer comprises single-crystalline silicon carbide (SiC) grown by a solution method.

6. The semiconductor device according to claim 2, wherein
a width of the first layer is smaller than a width of the second layer.

7. The semiconductor device according to claim 3, wherein
a difference between a width of the first layer and a width of the second layer is between 2 mm and 6 mm.

8. The semiconductor device according to claim 1, wherein
the covering layer is arranged to cover a bottom surface of the second layer.

9. The semiconductor device according to claim 1, wherein
a thickness of the covering layer is between 5 μm and 15 μm.

10. A method of manufacturing a semiconductor device, comprising:
forming an interface layer by implanting ionized impurities into a first layer comprising single-crystalline silicon carbide (SiC);
activating surfaces of the interface layer and a second layer comprising polycrystalline silicon carbide (SiC);
contacting and bonding the activated surfaces of the interface layer and the second layer; and
forming a covering layer to cover a top surface and sides of the first layer, sides of the interface layer, and sides of the second layer.

11. The method according to claim 10, wherein
the first layer is single-crystalline silicon carbide (SiC) that is grown by a solution method.

12. The method according to claim 10, wherein
the forming the covering layer comprises growing the covering layer epitaxially on the top surface and sides of the first layer, on the sides of the interface layer, and on the sides of the second layer.

13. The method according to claim 10, wherein
the forming covering layer comprises forming the covering layer to cover a top and sides of the first layer, the sides of the interface layer, the sides of the second layer, and a bottom surface of the second layer.
